(19) United States
(12) Patent Application Publication
(10) Pub. No.: US 2022/0136110 A1
(43) Pub. Date: May 5, 2022

(54) DE-ICING PROCESS AND PRODUCT

(71) Applicant: SILCOTEK CORP., Bellefonte, PA (US)

(72) Inventors: David A. SMITH, Bellefonte, PA (US); Gary A. BARONE, State College, PA (US); Geoffrey K. WHITE, State College, PA (US)

(21) Appl. No.: 17/511,953

(22) Filed: Oct. 27, 2021

Related U.S. Application Data
(60) Provisional application No. 63/107,903, filed on Oct. 30, 2020.

(51) Int. Cl. C23C 16/56; B64D 15/16; C23C 16/34

(52) U.S. Cl. CPC C23C 16/56; C23C 16/345; B64D 15/16

(57) ABSTRACT

De-icing processes and products with coatings enabling de-icing are disclosed. The de-icing process includes mechanically removing ice from a coated article having a chemical vapor deposition coating. The chemical vapor deposition coating includes silicon, carbon, and fluorine. The chemical vapor deposition coating is hydrophobic and oleophobic. The chemical vapor deposition coating remains hydrophobic and oleophobic after the mechanically removing of the ice. The product is a coated article having a chemical vapor deposition coating and ice on the chemical vapor deposition coating. The chemical vapor deposition coating includes silicon, carbon, and fluorine. The chemical vapor deposition coating is hydrophobic and oleophobic. The chemical vapor deposition coating remains hydrophobic and oleophobic in response to mechanically removing of the ice on the chemical vapor deposition coating.

### PRIORITY

The present application is a non-provisional patent application claiming priority and benefit of U.S. Provisional Patent Application No. 63/107,903, filed Oct. 30, 2020, and entitled “DE-ICING PROCESS AND PRODUCT,” the entirety of which is incorporated by reference.

### FIELD OF THE INVENTION

The present invention is directed to de-icing processes and to products with coatings enabling de-icing. More particularly, the present invention is directed to such processes and products enabled by coatings containing silicon, carbon, fluorine, and other constituents.

### BACKGROUND OF THE INVENTION

Ice causes many problems for processes. It builds up within processes, causing process failures and efficiency reductions. De-Icing often involves heating areas or spraying chemicals to remove ice. Physically removing ice can cause damage.

Some circumstances do not allow such heating. For example, thermally-sensitive components do not allow heating. Likewise, heating is not always possible (especially in extremely cold situations).

Some circumstances do not allow for such spraying of chemicals. For example, spraying of such chemical components may not be possible for components that need to be inert or remain free from contamination. In addition, the chemicals may be incompatible with other materials in proximity to components that have ice.

De-icing processes and products having coatings enabling de-icing that do not suffer from the above drawbacks would be desired in the art.

### BRIEF DESCRIPTION OF THE INVENTION

In an embodiment, a de-icing process includes mechanically removing ice from a coated article having a chemical vapor deposition coating. The chemical vapor deposition coating includes silicon, carbon, and fluorine. The chemical vapor deposition coating is hydrophobic and oleophobic. The chemical vapor deposition coating remains hydrophobic and oleophobic after the mechanically removing of the ice.

In another embodiment, a coated article includes a chemical vapor deposition coating and ice on the chemical vapor deposition coating. The chemical vapor deposition coating includes silicon, carbon, and fluorine. The chemical vapor deposition coating is hydrophobic and oleophobic. The chemical vapor deposition coating remains hydrophobic and oleophobic in response to mechanically removing of the ice on the chemical vapor deposition coating.

Other features and advantages of the present invention will be apparent from the following more detailed description, by way of example, describing the principles of the invention.

### DETAILED DESCRIPTION OF THE INVENTION

Provided are de-icing processes and products having chemical vapor deposition (CVD) coatings enabling the de-icing processes. The CVD coatings enabling such processes and substrates for such coatings are disclosed within U.S. Pat. No. 10,087,521, entitled “SILICON-NITRIDE-CONTAINING THERMAL CHEMICAL VAPOR DEPOSITION COATING,” U.S. Pat. No. 10,487,403, entitled “FLUORO-CONTAINING THERMAL CHEMICAL VAPOR DEPOSITION PROCESS AND ARTICLE,” and U.S. Pat. No. 10,604,660, entitled “WEAR RESISTANT COATING, ARTICLE, AND METHOD,” all of which are incorporated by reference in their entirety.

According to the disclosure, the de-icing processes is a mechanical/physical process enabled by a coating having silicon and carbon. In further embodiments, the coating includes nitrogen, oxygen, fluorine, and/or a variety of other constituents, such other elements, functional groups, and/or molecular fragments. Additionally or alternatively, embodiments include the de-icing being based upon heat being introduced, for example, at an amount that is less than necessary to remove ice on an uncoated surface.

Processes enabled include, but are not limited, those disclosed in “A Survey of Icephobic Coatings and Their Potential Use in a Hybrid Coating/Active Ice Protection System for Aerospace Applications,” Progress in Aerospace Sciences 105 (2019) 74-97, by Xiao Huang, et al., which is hereby incorporated by reference in its entirety (“Huang”). The aspects of Huang specifically referencing CVD suggest that the CVD coatings of the present invention should be incapable of resisting ice. The process of the present invention includes removing ice from the CVD coating with the CVD coating remaining present after the removal. The coated products of the present invention include enabling such removal.

Other processes include de-icing processes for components such as those disclosed in U.S. Patent Application Publication No. 2019/0100282, entitled “Article in Motion Comprising Hydrophobically-Coated Region,” the entirety of which is incorporated by reference.

In further embodiments, the mechanical/physical aspects of the de-icing process or the broader process of exposure for parts include or exclude heat. For example, in one embodiment, the temperature for the de-icing is below a maximum temperature. Suitable maximum temperatures include, but are not limited to, 7° C., 5° C., 3° C., 0° C., −10° C., −18° C., −30° C., or any suitable combination, sub-combination, range, or sub-range therein. Alternatively, in another embodiment, the parts are exposed to an exposure temperature without degrading the coating. Suitable exposure temperatures include, but are not limited to, 10° C., 20° C., 30° C., 50° C., 100° C., 200° C., 300° C., or any suitable combination, sub-combination, range, or sub-range therein.

### EXAMPLES

In a series of examples, in a standard food storage freezer (at 0° F./−18° C.), a variety of CVD coated surfaces and a control were placed in the freezer and 1-2 ml of deionized water at room-temperature was dropped on the middle of each CVD coated surface. The CVD coated surfaces were enclosed within the freezer for 16 hours.

The examples included a hydrophobic and oleophobic CVD coated surface with silicon, carbon, and fluorine, an untreated 316 stainless steel control, a hydrophilic and oleophilic CVD coated surface with silicon, carbon, and oxygen, a hydrophilic and oleophilic CVD coated surface with silicon, and a hydrophobic and oleophilic CVD coated surface with silicon, carbon, and oxygen.

Upon opening the freezer door, each coupon was individually removed and rapidly tested to avoid the potential impact of thawing. Each coupon was visually inspected, then a metal pick was used to laterally remove each ice ball from the surfaces. The degree of removal difficulty was subjectively rated on a scale of 1-10 (1=easy, 10=difficult) with accompanying observations.

The frozen droplet on the hydrophobic and oleophobic CVD coated surface with silicon, carbon, and fluorine was completely removed with relative ease, giving a rating of 3. Visually, the ice looked different from other tests being relatively transparent, with the ice staying together to resemble a cylinder. The hydrophobicity and oleophobicity of the CVD coated surface were later measured. The measurements suggested that the hydrophobicity and oleophobicity of the CVD coated surface were not reduced by the de-icing, thereby suggesting repeatability of the de-icing process.

The frozen droplet on the untreated 316 stainless steel control was difficult to remove, bulk chipped, and had minimal surface separation, giving a rating of 8. Visually, the ice looked opaque, with the ice flattening on the surface.

The frozen droplet on the hydrophilic and oleophilic CVD coated surface with silicon, carbon, and oxygen was difficult to remove, bulk chipped, and had minimal surface separation, giving a rating of 8. Visually, the ice looked opaque, with the ice flattening on the surface.

The frozen droplet on the hydrophilic and oleophilic CVD coated surface with silicon partially removed with substantial effort, giving a rating of 7. Visually, the ice looked opaque, with the ice flattening on the surface.

The frozen droplet on hydrophobic and oleophilic CVD coated surface with silicon, carbon, and oxygen was removed with notable effort, giving a rating of 6. The hydrophobicity of the CVD coated surface was later measured. The measurements suggested that the hydrophobicity were reduced by the de-icing, thereby suggesting limitations in repeatability of the de-icing process. Visually, the ice looked extremely opaque, even white, with the ice somewhat rising from the surface, but not to an almost cylindrical shape.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A coated article, comprising:
a chemical vapor deposition coating;
ice on the chemical vapor deposition coating;
wherein the chemical vapor deposition coating includes silicon, carbon, and fluorine;
wherein the chemical vapor deposition coating is hydrophobic and oleophobic;
wherein the chemical vapor deposition coating remains hydrophobic and oleophobic in response to mechanically removing of the ice on the chemical vapor deposition coating.

2. The coated article of claim 1, wherein the coated article is positioned on a wing.

3. The coated article of claim 2, wherein the coated article is positioned on an erosion shield of the wing.

4. The coated article of claim 2, wherein the coated article is positioned on is an erosion shield of the wing.

5. The coated article of claim 2, wherein the coated article is a coil on the wing.

6. The coated article of claim 2, wherein the coated article is a sensor on the wing.

7. The coated article of claim 2, wherein the coated article is an actuator on the wing.

8. The coated article of claim 1, wherein the coated article is a wing.

9. The coated article of claim 1, wherein the coated article is a nozzle on an aircraft.

10. The coated article of claim 1, wherein the coated article is a propeller.

11. The coated article of claim 1, wherein the coated article is a portion of landing gear.

12. The coated article of claim 1, wherein the coated article is an antenna.

13. The coated article of claim 1, wherein the coated article is a fuselage nose.

14. The coated article of claim 1, wherein the coated article is a fuel tank vent.

15. The coated article of claim 1, wherein the coated article is a fuel tip tank.

16. The coated article of claim 1, wherein the coated article is an engine inlet.

17. The coated article of claim 1, wherein the coated article is a grating.

18. A vehicle containing the coated article of claim 1, wherein the system is an aircraft.

19. A structure containing the coated article of claim 1, wherein the structure is a wind turbine.

20. A de-icing process, comprising:
mechanically removing ice from a coated article having a chemical vapor deposition coating;
wherein the chemical vapor deposition coating includes silicon, carbon, and fluorine;
wherein the chemical vapor deposition coating is hydrophobic and oleophobic;
wherein the chemical vapor deposition coating remains hydrophobic and oleophobic after the mechanically removing of the ice.
